(19) United States
(12) Patent Application Publication
(10) Pub. No.: US 2015/0357232 A1
(43) Pub. Date: Dec. 10, 2015

(54) METHOD FOR MANUFACTURING SEMICONDUCTOR DEVICE

(71) Applicant: PS4 Luxco S.a.r.l., Luxembourg (LU)

(72) Inventor: Shingo Ujihara, Tokyo (JP)

(21) Appl. No.: 14/759,898

(22) PCT Filed: Jan. 14, 2014
(86) PCT No.: PCT/JP2014/050450

§ 371 Date: Jul. 8, 2015

(30) Foreign Application Priority Data
Jan. 22, 2013 (JP) 2013-008918

(51) Int. Cl. H01L 21/762; H01L 21/3105

(52) U.S. Cl. CPC H01L 21/76229; H01L 21/31056

(57) ABSTRACT

One method for manufacturing a semiconductor device includes forming element isolation grooves and an element isolation groove having a width greater than that of the element isolation grooves in the semiconductor substrate, forming insulating films having relatively low fluidity and having upwardly released voids inside the element isolation grooves, and also covering substantially all of the interior surface of the element isolation groove, forming an insulating film having relatively high fluidity, whereby the insulating film is embedded in the interior of the voids, and reforming the insulating film.

### TECHNICAL FIELD

The present invention relates to a method for manufacturing a semiconductor device, and in particular the present invention relates to a method for manufacturing a semiconductor device having a plurality of element isolation regions that have different aspect ratios (the ratio of trench depth to trench width).

### BACKGROUND

In a semiconductor device such as a DRAM (Dynamic Random Access Memory), an insulating film (element isolation insulating film) is provided between adjacent elements, and insulation is maintained between elements as a result. The element isolation insulating film is formed by embedding an insulating film in a trench (element isolation trench) provided in a semiconductor substrate, but the aspect ratio of element isolation trenches has increased as miniaturization has advanced in recent years, and it has become difficult to reliably embed an insulating film inside an element isolation trench.

A SOD (Spin-On Dielectric) method employing polysilazane is known as a method that enables an insulating film to be reliably embedded within an element isolation trench having a large aspect ratio (see Patent Document 1). According to this method, polysilazane endowed with high fluidity is first of all formed as a film by means of spin coating. Here, the polysilazane has high fluidity, and therefore it permeates well into the element isolation trench having a large aspect ratio. Annealing is then carried out in order to modify and cure the polysilazane. An element isolation insulating film formed by a SOD method is completed by means of the abovementioned process.

### Patent Documents

Patent Document 1: JP 2010-263129 A

### SUMMARY OF THE INVENTION

### Problem to be Solved by the Invention

With the abovementioned SOD method, however, there are problems in that dislocation defects may occur within the semiconductor substrate, especially in relation to element isolation trenches having a small aspect ratio (element isolation trenches having a large width). Specifically, volumetrically shrinkage of the polysilazane occurs in the annealing included in the SOD method. Stress is produced inside the semiconductor substrate when the volume of the polysilazane shrinks, and dislocation defects are produced inside the semiconductor substrate by this stress. This stress increases the greater the amount of polysilazane inside the element isolation trench, so dislocation defects are likely to be produced in semiconductor substrates around element isolation trenches having a small aspect ratio.

Dislocation defects in a semiconductor substrate are a cause of current leakage. There is therefore a need for a method that enables an insulating film to be reliably embedded in an element isolation trench without dislocation defects being produced in the semiconductor substrate.

### Means for Solving the Problem

The method for manufacturing a semiconductor device according to the present invention is characterized in that it comprises the following steps: a step in which a first element isolation trench and a second element isolation trench which is wider than the first element isolation trench are formed in a semiconductor substrate; a step in which a first insulating film is formed, said first insulating film having relatively low fluidity and forming a void which opens upward inside the first element isolation trench while also covering substantially the whole of the inner surface of the second element isolation trench; a step in which a second insulating film having relatively high fluidity is formed, whereby said second insulating film fills the void; and a step in which the second insulating film is modified.

### Advantage of the Invention

According to the present invention, a second insulating film having relatively high fluidity does not come into contact with the inner surface of a wide second element isolation trench (the surface of a semiconductor substrate) at the stage of modification. This makes it possible to reduce the likelihood of dislocation defects occurring in the semiconductor substrate due to volumetric shrinkage of the second insulating film as it is modified.

### BRIEF DESCRIPTION OF THE FIGURES

FIG. 1 is a process diagram showing the steps of the method for manufacturing a semiconductor device according to preferred first and second modes of embodiment of the present invention;

FIG. 2 (a)-(c) is a process diagram showing the steps of the method for manufacturing a semiconductor device according to the preferred first mode of embodiment of the present invention;

FIG. 3 (a)-(c) is a process diagram showing the steps of the method for manufacturing a semiconductor device according to the preferred first mode of embodiment of the present invention;

FIG. 4 (a)-(c) is a process diagram showing the steps of the method for manufacturing a semiconductor device according to the preferred second mode of embodiment of the present invention;

FIG. 5 (a)-(c) is a process diagram showing the steps of the method for manufacturing a semiconductor device according to the preferred second mode of embodiment of the present invention; and

FIG. 6 is a diagram showing the relationship of film thickness H shown in FIG. 4(c) and the number of dislocation defects occurring in a semiconductor substrate 2.

Preferred modes of embodiment of the present invention will be described in detail below with reference to the appended figures.

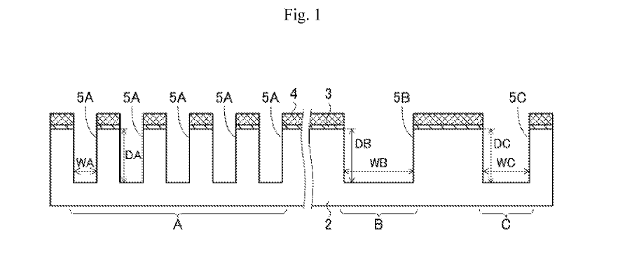

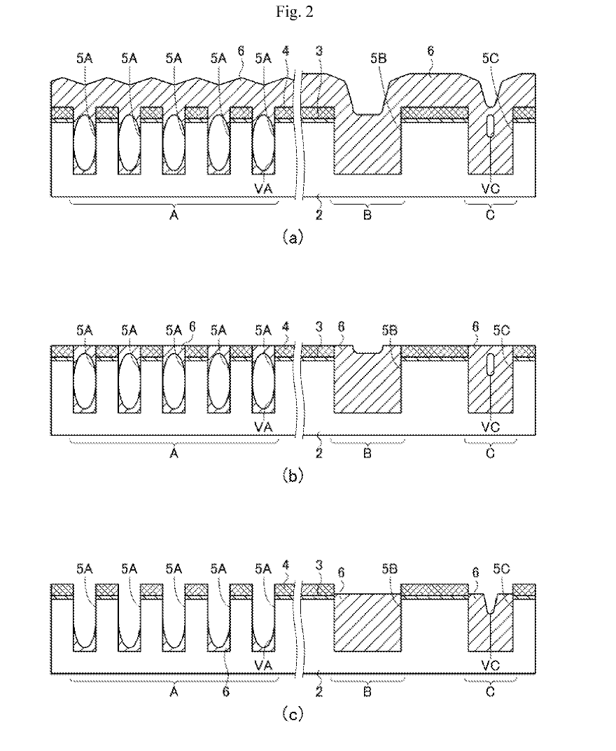

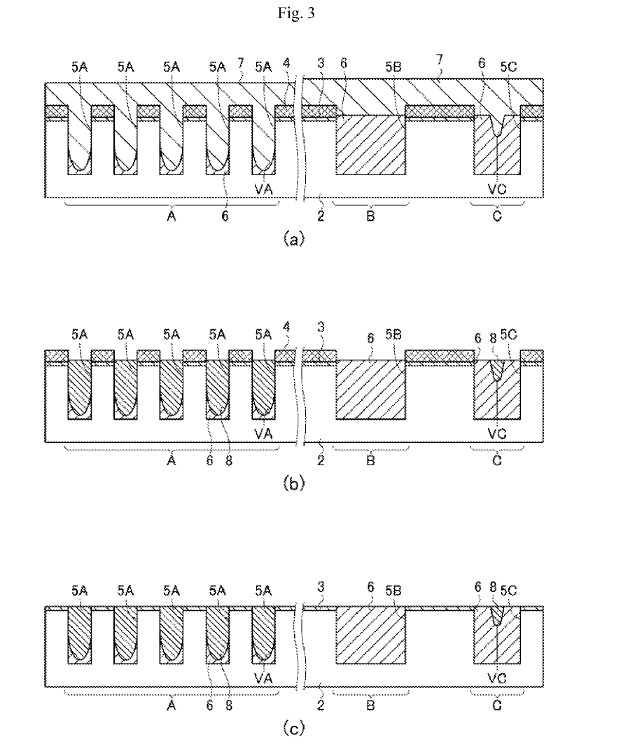

FIG. 1, FIG. 2(a)-(c) and FIG. 3(a)-(c) are process diagrams showing the steps of the method for manufacturing a semiconductor device according to a preferred first mode of embodiment of the present invention. The semiconductor device which is manufactured by means of the manufacturing method according to this mode of embodiment is a semiconductor device such as a DRAM, for example, which is provided with a memory cell array and peripheral circuits (column decoder, row decoder, read/write amplifier, command input circuit, address input circuit, data input/output circuit etc.), although these are not depicted.

A region A in FIG. 1 is a region in which a memory cell array is formed (memory cell array region), and a plurality of element isolation trenches 5A (first element isolation trenches) each having a width WA and a depth DA are formed in that region. An insulating film (element isolation insulating film) is embedded in each of the plurality of element isolation trenches 5A by means of a process to be described later, and adjacent memory cells are electrically isolated by means of the insulating films.

Furthermore, the regions B, C shown in FIG. 1 are regions in which the peripheral circuits are formed (peripheral circuit regions), and element isolation trenches 5B, 5C (second element isolation trenches) having a width WB, WC and a depth DB, DC, respectively, are formed in those regions. It should be noted that the widths WA-WC are set in such a way as to satisfy the relationship WA<WC<WB, and the depths DB, DC are actually formed to be slightly deeper the greater the width, but they are shown here set in such a way as to satisfy the relationship DA=DB=DC for the sake of simplicity. In FIG. 1, one each of the element isolation trenches 5B, 5C are drawn, but in actual fact a plurality of the element isolation trenches 5B, 5C are formed. Furthermore, element isolation trenches having a width value other than WB or WC are also formed in actual fact. An insulating film (element isolation insulating film) is also embedded in the element isolation trenches 5B, 5C by means of a process to be described later, and adjacent circuits are electrically isolated by means of the insulating film.

As shown in the example in FIG. 1, the element isolation trenches in the peripheral circuit region are generally wider than those formed in the memory cell array region. The depth is often not vastly different from the width, which means that there are more element isolation trenches having a small aspect ratio in comparison with the element isolation trenches formed within the memory cell array region. In view of this, the two element isolation trenches 5B, 5C in which the depths DB, DC are both equal to the depth DA, and the widths WB, WC are both greater than the width WA are shown as typical examples in the regions B, C in FIG. 1.

The method for manufacturing a semiconductor device according to this mode of embodiment will be described in detail below.

A pad oxide film 3 for protecting the surface of a semiconductor substrate (a silicon substrate) 2 is first of all formed by thermal oxidation of said surface. A silicon nitride film 4 (mask film) is then formed over the whole surface. A photoresist which is not depicted is then applied and patterned to form the pattern of the element isolation trenches 5A-5C. The silicon nitride film 4, pad oxide film 3 and semiconductor substrate 2 are then etched using the patterned photoresist as a mask, whereby the element isolation trenches 5A-5C are formed, as shown in FIG. 1. It should be noted that the etching is preferably carried out using an inductively-coupled plasma etching apparatus; a CF₄/CHF₃ gas system is preferably used as the reaction gas when the silicon nitride film 4 is etched, and an HBr/Cl₂/SF₆ gas system is preferably used as the reaction gas when the pad oxide film 3 and semiconductor substrate 2 are etched, the gas pressure being set at 20 mTorr in either case. The etching time is preferably set in such a way that the depth DA of the element isolation trenches 5A is approximately 250 nm-300 nm. The side walls of the element isolation trenches 5A-5C which are formed at this point are actually slightly tapered the greater the width of the trenches, but they are shown as vertical side walls for the sake of simplicity in FIG. 1.

Next, an insulating film 6 (first insulating film) is formed by means of the steps in FIG. 2(a) to FIG. 2(c), said insulating film 6 having relatively low fluidity and forming voids which open upward inside the element isolation trenches 5A while also covering substantially the whole of the inner surface of the element isolation trenches 5B, 5C. This will be described in detail below.

As shown in FIG. 2(a), the insulating film 6 (a silicon dioxide film) is first of all formed to a thickness that covers substantially the whole of the inner surfaces of the element isolation trenches 5B, 5C, respectively. To be more specific, the amount of the insulating film 6 which is formed is set in such a way that a position on the upper edge of the insulating film 6 inside the widest element isolation trench 5B is at the same level or at a higher level than the upper surface of the semiconductor substrate 2, after a step in which the insulating film 6 is removed (FIG. 2(c)) (to be described later). The specific film formation method which is employed is preferably any of an HDP-CVD (High-Density Plasma Chemical Vapor Deposition), thermal CVD (Chemical Vapor Deposition), LP-CVD (Low-Pressure Chemical Vapor Deposition) or ALD (Atomic Layer Deposition) method. These methods will be described in detail below.

When an HDP-CVD method is used, a film is preferably formed employing an SiH₄/O₂/H₂ gas as the reaction gas, with the plasma generation high-frequency power and ion-attraction high-frequency power both at 9000 W. In this case, the insulating film 6 is an HDP oxide film.

When a thermal CVD method is used, a film is preferably formed at a temperature of 700° C. employing an SiH₄/N₂O gas as the reaction gas. In this case, the treatment time should be determined in accordance with the required film thickness.

When the LP-CVD method is used, a film is preferably formed at a temperature of 700° C. employing tetraethoxysilane (TEOS)/O₂ as the reaction gas. In this case too, the treatment time should be determined in accordance with the required film thickness.

When the ALD method is used, a film is preferably formed at a temperature of 700° C. employing dichlorosilane as a starting material gas, N₂O as an oxidizing gas, and nitrogen as an inert gas. It should be noted that the ALD method requires, for each atomic layer, that a procedure be repeated in which the starting material gas is reacted, the inert gas is used for purging, the oxidizing gas is reacted, and the inert gas is once again used for purging, so a longer film-formation time is required in comparison with the other methods. Therefore, when a thick film is needed, a method other than the ALD method is preferably adopted.

With the abovementioned methods, insufficient reaction gas enters the relatively narrow element isolation trenches 5A, so a void VA is formed in the element isolation trenches 5A. The insulating film 6 is formed as normal on the upper surface of the silicon nitride film 4 on both sides of the element isolation trenches 5A, so the upper part of the voids VA is closed by the insulating film 6, as shown in FIG. 2(a). Voids VC are likewise also formed inside the element isolation trenches 5C which have an intermediate width between that of the element isolation trenches 5B and the element isolation trenches 5A, although the voids VC are narrower than the voids VA. The element isolation trenches 5B which are relatively wide are filled by the insulating film 6 because sufficient reaction gas can enter.

Next, as shown in FIG. 2(b), CMP (Chemical Mechanical Polishing) is carried out until the silicon nitride film 4 is exposed, and as shown in FIG. 2(c), the insulating film 6 is selectively etched back in order to remove the portion of the insulating film 6 formed above the voids VA. As a result, the voids VA constitute voids which open upward and are formed inside the element isolation trenches 5A, as shown in FIG. 2(c). The voids VC likewise constitute voids which open upward. It should be noted that the transverse width of the voids VC is slightly increased by this removal, as will be clear from comparing FIG. 2 (b) and FIG. 2(c).

The insulating film 6 is preferably etched back in the abovementioned removal step specifically by means of wet etching. Furthermore, the etching conditions are preferably set in such a way as to maintain a state in which the upper edge of the insulating film 6 inside the element isolation trenches 5B is positioned at the same level as or above the upper surface of the semiconductor substrate 2. It should be noted that the mention of the “upper edge” in this instance means that although there are times when the center region of the upper surface of the insulating film 6 inside the element isolation trenches 5B is depressed due to the CMP dishing effect, a state is maintained in which at least the edge of the upper surface of the insulating film 6 (the portion in contact with the silicon nitride film 4 etc.) is positioned at the same level as or above the upper surface of the semiconductor substrate 2.

Next, as shown in FIG. 3(a), an insulating film 7 (second insulating film) having relatively high fluidity is formed, whereby the insulating film 7 fills the voids VA. At this point, the insulating film 7 also fills the voids VC.

Specifically, the insulating film 7 is preferably formed by activating a trisilylamine (TSA) and ammonia (NH₃) gas in plasma using an FCVD (Flowable CVD) apparatus. As a result, the polysilazane (FCVD oxide film) formed by means of the FCVD method has high fluidity and can completely fill the inside of the voids VA, VC. It should be noted that in addition to the FCVD method, the abovementioned SOD method may also be adopted. The SOD method also makes it possible to form an insulating film that has high fluidity and can completely fill the inside of the voids VA, VC.

Once formation of the insulating film 7 has been completed, the insulating film 7 is then modified (densified) by means of heat treatment in an ozone atmosphere. As a result, the insulating film 7 is converted to the insulating film 8 shown in FIG. 3(b). The insulating film 8 has little fluidity and specifically is an amorphous silicon dioxide film. It should be noted that an additional heat treatment may be performed in an annealing furnace, as well as the heat treatment in an ozone atmosphere.

CMP is then carried out until the silicon nitride film 4 is exposed, and the insulating film 8 is then etched back to a height corresponding to the pad oxide film 3. The etching back is preferably carried out by means of wet etching having a higher etching rate with respect to the silicon dioxide film. By means of this step, only the silicon nitride film 4 is projecting, as shown in FIG. 3(b).

The silicon nitride film 4 is then removed by means of wet etching employing hot phosphoric acid. With this removal, the etching rate of the silicon dioxide film is far smaller than the etching rate of the silicon nitride film, so the silicon nitride film 4 is removed, after which it is possible to obtain a smooth surface, as shown in FIG. 3(c). The element isolation insulating film is completed at positions corresponding to the element isolation trenches 5A-5C by means of the steps up to this point.

After this, the semiconductor device which is a DRAM is completed by implementing processes which are the same as conventional processes, such as forming an insulating film covering the peripheral circuit regions (the regions B and C), and forming gate electrodes for memory cells in the memory cell array region (the region A), although these processes are not depicted.

As described above, with the method for manufacturing a semiconductor device according to this mode of embodiment, the insulating film 7 does not come into contact with the inner surface of the wide element isolation trenches 5B, 5C at the stage of modification of the insulating film 7 (FIG. 3(a)). This makes it possible to reduce the likelihood of dislocation defects occurring in the semiconductor substrate 2 due to volumetric shrinkage of the insulating film 7 as it is modified.

It should be noted that the present invention is based on the finding that, even if heat treatment for modifying the insulating film 7 having fluidity causes shrinkage of said film having fluidity, dislocation defects occurring on the semiconductor substrate 2 are suppressed to an extent that can be substantially ignored if the insulating film 6 which substantially does not have fluidity is disposed to a sufficient thickness between the film having fluidity and the semiconductor substrate 2, and the insulating film 6 which substantially does not have fluidity can fill the element isolation trenches 5B having a small aspect ratio essentially without the formation of voids etc. According to the present invention and on the basis of this finding, the insulating film 6 which substantially does not have fluidity is first of all deposited on the semiconductor substrate 2 having trenches of differing widths (the element isolation trenches 5A-5C), after which the insulating film 7 having fluidity is formed. As a result, it is possible to considerably suppress or completely suppress the formation of the insulating film 7 inside the wide element isolation trenches 5C, and therefore it is possible to suppress the formation of dislocation defects produced around the element isolation trenches 5C which occur in a conventional method that does not employ the insulating film 6. Meanwhile, even if the insulating film 6 which substantially does not have fluidity is not formed for the most part in the element isolation trenches 5A having a small width, the insulating film 7 having fluidity can still be embedded therein. It should be noted that the element isolation trenches 5A have a small volume, so the likelihood of the formation of dislocation defects around the element isolation trenches 5A is small enough that it can be ignored.

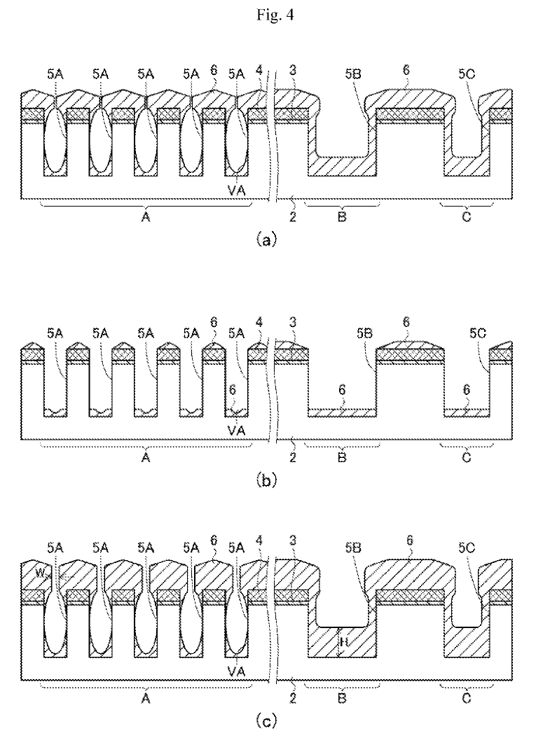

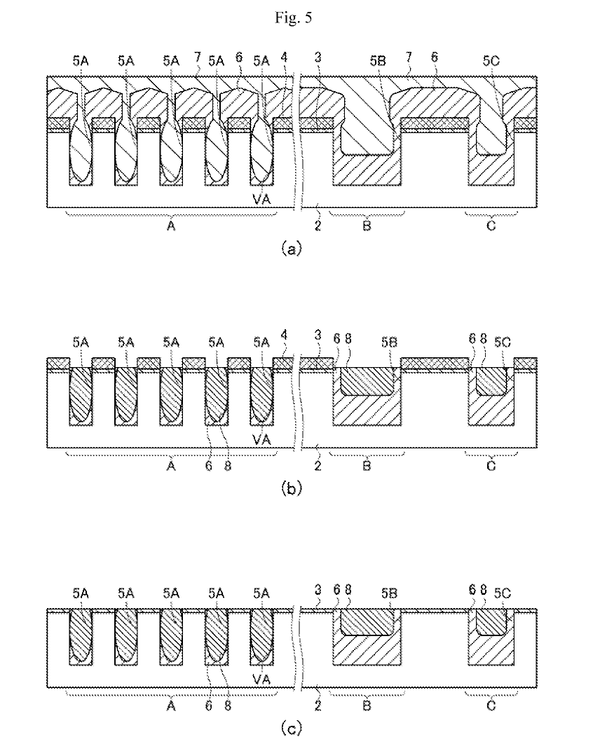

FIG. 4(a)-(c) and FIG. 5(a)-(c) are process diagrams showing the steps of the method for manufacturing a semiconductor device according to the preferred second mode of embodiment of the present invention. The manufacturing method according to this mode of embodiment is the same as in the first mode of embodiment except that the order of formation and removal of the insulating film 6 is different. The following description will focus on the differences with the first mode of embodiment.

The steps up to the formation of the element isolation trenches 5A-5C are as described in the first mode of embodiment with reference to FIG. 1. After the element isolation trenches 5A-5C have been formed, the insulating film 6 (first insulating film) is formed, said insulating film 6 having relatively low fluidity and forming voids which open upward inside the element isolation trenches 5A while also covering substantially the whole of the inner surfaces of the element isolation trenches 5B, 5C. This will be described in detail below.

The insulating film 6 (a silicon dioxide film) having relatively low fluidity is first of all formed to a thickness that covers substantially the whole of the inner surface of the element isolation trenches 5B, 5C, as shown in FIG. 4(a). The film formation method and film formation conditions may be the same as in the first mode of embodiment, but in this mode of embodiment, the film formation time is shorter than the film formation time in the first mode of embodiment. That is to say, in the first mode of embodiment, the amount of the insulating film 6 which is formed was set in such a way that the upper surface of the insulating film 6 inside the widest element isolation trench 5B is at a higher level than the upper surface of the semiconductor substrate 2, but in this mode of embodiment, the amount of the insulating film 6 which is formed is set in such a way the upper surface of the insulating film 6 inside the widest element isolation trench 5B is positioned at around half the height of the element isolation trench 5B. As a result, the insulating film 6 is formed in the shape of the side walls over the upper half of the element isolation trenches 5B.

After the insulating film 6 has been formed, the voids VA which are the same as in the first mode of embodiment are formed inside the element isolation trenches 5A, as shown in FIG. 4(a). However, in this mode of embodiment, only a small amount of the insulating film 6 is formed, so the voids VA are not necessarily closed voids and they may open upward, as shown in the example in FIG. 4(a).

The portion of the insulating film 6 formed above the voids VA is then removed by selectively etching back the insulating film 6, as shown in FIG. 4(b). The etch-back time is a sufficiently short time for the insulating film 6 to remain at the bottom part of the element isolation trenches 5B, 5C. Selective wet etching of the silicon dioxide film is preferably used as the specific etch-back method, but selective dry etching of the silicon dioxide film equally be used, depending on the state of closure of the voids VA.

The insulating film 6 is then once again formed to a thickness that covers substantially the whole of the inside surface of the element isolation trenches 5B, 5C while a state is maintained in which the voids VA open upward, as shown in FIG. 4(c). The film formation method and film formation conditions which are used are preferably the same as when the insulating film 6 is formed for the first time. The insulating film 6 has to be formed in such a way that the width W of the upward openings of the voids VA is 10 nm±10% and the film thickness H of the insulating film 6 positioned on the bottom surface of the element isolation trenches 5B, 5C is at least 30 nm. This point will be described again in detail after all of the steps have been described.

It should be noted that after the insulating film 6 has been formed once again, a microscope or the like is preferably used to confirm that the width W is actually 10 nm±10% and that the film thickness H is actually at least 30 nm. If the result of the confirmation shows that either the width W or the film thickness H of any of the chips is not within the corresponding range, those chips are preferably discarded.

Next, as shown in FIG. 5(a), an insulating film 7 (second insulating film) having relatively high fluidity such as polysilazane is formed, and as a result the insulating film 7 fills the voids VA. At this point, the insulating film 7 is also embedded inside the element isolation trenches 5B, 5C. The specific film formation method and film formation conditions for the insulating film 7 should be the same as in the case of the first mode of embodiment described with reference to FIG. 3(a). It should be noted that the amount of the insulating film 7 which is formed is preferably sufficient that the upper surface of the insulating film 6 formed on the upper surface of the silicon nitride film 4 can be covered by the insulating film 7.

The subsequent steps are the same as in the first mode of embodiment. That is to say, the insulating film 7 is modified (densified) as a result of heat treatment in an ozone atmosphere and converted to the insulating film 8 which is an amorphous silicon dioxide film. CMP is then carried out until the silicon nitride film 4 is exposed and the insulating film 8 is then etched back to a height corresponding to the pad oxide film 3. As a result, only the silicon nitride film 4 is projecting, as shown in FIG. 5(b), and therefore the silicon nitride film 4 is etched back by means of wet etching employing hot phosphoric acid. As a result, a flat surface is obtained, as shown in FIG. 5(c). The element isolation insulating film is completed at positions corresponding to the element isolation trenches 5A-5C by means of the steps up to this point.

As described above, the insulating film 7 does not come into contact with the inner surface of the wide element isolation trenches 5B, 5C at the stage in which the insulating film 7 is modified (FIG. 5(a)) as a result of the method for manufacturing a semiconductor device according to this mode of embodiment. This makes it possible to reduce the likelihood of dislocation defects occurring in the semiconductor substrate 2 due to volumetric shrinkage of the insulating film 7 as it is modified.

Furthermore, CMP has to be carried out twice in the first mode of embodiment (CMP of the insulating film 6 and CMP of the insulating film 8), but in this mode of embodiment it is not necessary to perform CMP for the insulating film 6. That is to say, it is possible to reduce the number of times that CMP is implemented, so the method for manufacturing a semiconductor device according to this mode of embodiment achieves lower manufacturing costs than in the first mode of embodiment.

Returning to FIG. 4(c), suitable values for the width W of the upward openings of the voids VA and the film thickness H of the insulating film 6 will be described.

Looking first at the width W, the upward openings of the voids VA form an entrance for the insulating film 7 when said insulating film 7 fills the voids VA in the step shown in FIG. 5(a). The width W therefore has to be a sufficiently large value to ensure the smooth ingress of the insulating film 7.

Table 1 shows the result of confirming film formation results for the insulating film 7 inside the voids VA in terms of the width W, for various values of the width W. As shown in the table, when the width W is 5 nm or less, it is not possible to form the insulating film 7 in a normal manner inside the voids VA. On the other hand, when the width W is 10 nm or greater, it is possible to form the insulating film 7 in a normal manner inside the voids VA. The amount of film formation etc. of the insulation film 7 therefore has to be determined in such a way that the width W is 10 nm±10%. It should be noted that ±10% is the variation (error) included in the actual process.

TABLE 1

W

| | 15 nm | 10 nm | 5 nm | 3 nm |
|---|---|---|---|---|
| Film formation result | OK | OK | NG | NG |

Looking next at the height H, the film thickness H denotes the distance between the insulating film 7 and the semiconductor substrate 2, and the smaller the film thickness H, the more volumetric shrinkage of the insulating film 7 accompanying modification is likely to affect the semiconductor substrate 2.

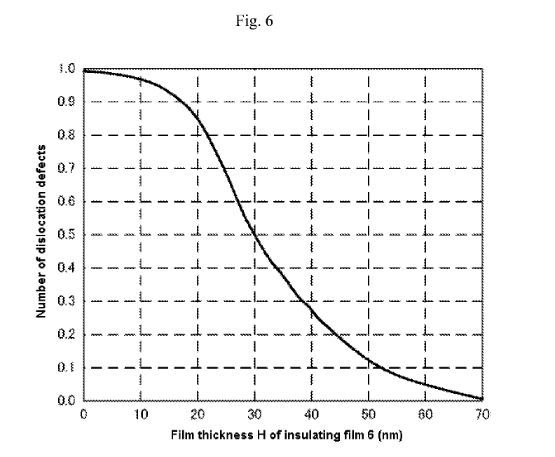

FIG. 6 is a diagram showing the relationship of film thickness H and the number of dislocation defects occurring in the semiconductor substrate 2. In FIG. 6, the horizontal axis shows the film thickness H and the vertical axis shows the number of dislocation defects occurring in the semiconductor substrate 2. It should be noted that relative values are used, taking the number of dislocation defects occurring in the semiconductor substrate 2 when the insulating film 6 is not formed as 1. As shown in FIG. 6, the number of dislocation defects decreases the greater the film thickness H. The film thickness H is therefore preferably as great as possible from the point of view of the number of dislocation defects, but increasing the film thickness H leads to a reduction in the width W. Furthermore, increasing the film thickness H increases the film formation time, which is to say the manufacturing costs, so when the actual film thickness H is determined, the permitted upper limit value for the number of dislocation defects is preferably ascertained and then the smallest possible value in a range such that the number of dislocation defects is no greater than the upper limit value is preferably adopted. In the case of a DRAM, the permitted upper limit value for the number of dislocation defects is 0.5 based on FIG. 6, so it can be said that a film thickness H of 30 nm or greater is preferred.

Preferred modes of embodiment of the present invention were described above, but the present invention is not limited to the abovementioned modes of embodiment and various modifications may be made within a scope that does not depart from the essential point of the present invention, and it goes without saying that any such modifications are included in the scope of the present invention.

For example, in the modes of embodiment described above, the insulating film 6 covers substantially the whole of the inner surfaces of the element isolation trenches 5B, 5C; “substantially” as referred to herein means that coverage should be in a range such that the abovementioned “permitted upper limit value for the number of dislocation defects” is satisfied. That is to say, even if the films are exposed in such a way that part of the inner surfaces of the element isolation trenches 5B, 5C is not covered by the insulating film 6 at the stage in FIG. 4(c), for example, the abovementioned “permitted upper limit value for the number of dislocation defects” may still be satisfied after modification of the insulating film 7, depending on the exposed area etc. The term “substantially” means that the present invention also includes such cases.

### Key to Symbols

2 Semiconductor substrate
3 Pad oxide film
4 Silicon nitride film
5A-5C Element isolation trenches
6-8 Insulating film
VA, VC Void

1. A method for manufacturing a semiconductor device, comprising:
forming a first element isolation trench and a second element isolation trench which is wider than the first element isolation trench in a semiconductor substrate;
forming a first insulating film, said first insulating film having relatively low fluidity and forming a void which opens upward inside the first element isolation trench while also covering substantially the whole of the inner surface of the second element isolation trench;
forming a second insulating film having relatively high fluidity, whereby said second insulating film fills the void; and
a step in which modifying the second insulating film.

2. The method of claim 1, wherein forming the first insulating film comprises:
forming the first insulating film to a thickness that covers substantially the whole of the inner surface of the second element isolation trench; and
removing a portion of the first insulating film formed above the void while a state in which substantially the whole of the inner surface of the second element isolation trench is covered by the first insulating film is maintained.

3. The method of claim 2, wherein the amount of the first insulating film which is formed is set in such a way that a position on the upper edge of the first insulating film inside the second element isolation trench is at the same level or at a higher level than the upper surface of the semiconductor substrate, after removing the portion of the first insulating film.

4. The method of claim 2, wherein forming the first and second element isolation trenches comprises:
forming a mask film on the surface of the semiconductor substrate; and
forming the first and second element isolation trenches by selectively removing the semiconductor substrate using the mask film as a mask.

5. The method of claim 4, wherein removing the portion of the first insulating film comprises:
performing CMP until the mask film is exposed; and
etching back the first insulating film after the CMP.

6. The method of claim 2, comprising:
performing CMP until the mask film is exposed, after modifying the second insulating film.

7. The method of claim 1, wherein forming the first insulating film comprises:
forming the first insulating film to a thickness that covers substantially the whole of the inner surface of the second element isolation trench;
removing a portion of the first insulating film formed above the void; and
forming the first insulating film once again to a thickness that covers substantially the whole of the inner surface of the second element isolation trench while a state in which the void opens upward is maintained.

8. The method of claim 7, wherein removing the portion of the first insulating film is carried out by etching back the first insulating film.

9. The method of claim 7, wherein forming the first and second element isolation trenches comprises:
forming a mask film on the surface of the semiconductor substrate; and
forming the first and second element isolation trenches by selectively removing the semiconductor substrate using the mask film as a mask.

10. The method of claim 9, comprising:
performing CMP until the mask film is exposed, after modifying the second insulating film.

11. The method of claim 1, wherein the first insulating film and the second insulating film both comprise a silicon dioxide film.

12. The method of claim 2, wherein forming the first insulating film is carried out using any of an HDP-CVD, thermal CVD, LP-CVD or ALD method.

13. The method of claim 1, wherein forming the second insulating film is carried out by means of an FCVD or SOD method.
